(19) United States
(12) Patent Application Publication
(10) Pub. No.: US 2025/0284404 A1
(43) Pub. Date: Sep. 11, 2025

(54) MEMORY SYSTEM AND CONTROL METHOD THEREOF, AND ELECTRONIC APPARATUS

(71) Applicant: YANGTZE MEMORY TECHNOLOGIES CO., LTD., Wuhan (CN)

(72) Inventors: TingTing WANG, Wuhan (CN); Ting ZHU, Wuhan (CN)

(21) Appl. No.: 19/011,421

(22) Filed: Jan. 6, 2025

(30) Foreign Application Priority Data
Mar. 8, 2024 (CN) 2024102688518

(51) Int. Cl. G06F 3/06

(52) U.S. Cl. CPC G06F 3/0617; G06F 3/0659; G06F 3/0679

(57) ABSTRACT

Examples of the present disclosure disclose a memory system and a control method thereof, and an electronic apparatus. The memory system includes one or more memory devices and a memory controller. The memory controller is coupled with the memory devices and configured to: store a count of suspend operations performed in response to suspend instructions, and after receiving a suspend instruction, perform the suspend operations upon determining that the count of performed suspend operations corresponding to a type of a current operation is less than or equal to a preset value corresponding to the type of the current operation.

### CROSS-REFERENCE TO RELATED APPLICATIONS

This application claims the benefit of priority to China Patent Application No. CN 2024102688518, filed on Mar. 8, 2024, which is incorporated herein by reference in its entirety.

### TECHNICAL FIELD

Examples of the present disclosure relate to semiconductor technologies, and relate to, but not limited to, a memory system and a control method thereof, and an electronic apparatus.

### BACKGROUND

A Non-Volatile Memory (NVM) acts as a core memory device for Solid State Drives (SSD), with the advantages such as non-volatility, a high storage density, and read and write speeds much higher than those of the hard drive, and is widely applied in the industry. The most basic operations of the non-volatile memory are read, write, and erase operations, and these basic operations cover basic applications of the SSD. In addition, the non-volatile memory may also perform some operations with advanced features, such as program/erase suspension and program/erase resumption, etc.

### SUMMARY

In view of this, examples of the present disclosure provide a memory system and a control method thereof, and an electronic apparatus.

According to one aspect of the present application provides a memory system. The memory system comprises one or more memory devices and a memory controller. The memory controller is coupled with the memory devices and configured to: store a count of suspend operations performed in response to suspend instructions, and after receiving a suspend instruction, perform a suspend operation upon determining that the count of the performed suspend operations corresponding to a type of a current operation is less than or equal to a preset value corresponding to the type of the current operation.

In some examples, after receiving the suspend instruction, the memory system is further configured to: when the count of the performed suspend operations corresponding to the type of the current operation is greater than the preset value corresponding to the type of the current operation, continue to perform the current operation without responding to the suspend instruction; and upon performing the suspend operation in response to the suspend instruction when the count of the performed suspend operations corresponding to the type of the current operation is less than or equal to the preset value corresponding to the type of the current operation, add one to the count of the performed suspend operations corresponding to the type of the current operation and store the count in the memory controller.

In some examples, the type of the current operation comprises any one of a program operation, an erase operation, or a read operation; the suspend operation comprises one or more of a program suspend operation, an erase suspend operation, and a read suspend operation.

In some examples, the current operation comprises a program operation; the preset value comprises a maximum program suspend threshold; the performed suspend operations comprise performed program suspend operations.

The memory controller is configured to: during the program operation, receive the suspend instruction, determine a magnitude relationship between a count of the performed program suspend operations and the maximum program suspend threshold, and determine whether to perform the suspend operation in response to the suspend instruction.

In some examples, the current operation comprises an erase operation; the preset value comprises a maximum erase suspend threshold; the performed suspend operations comprise performed erase suspend operations.

The memory controller is configured to: during the erase operation, receive the suspend instruction, determine a magnitude relationship between a count of the performed erase suspend operations and the maximum erase suspend threshold, and determine whether to perform the suspend operation in response to the suspend instruction.

In some examples, the preset value comprises a maximum erase pulse suspend threshold; the performed suspend operations comprise performed erase pulse suspend operations.

The memory controller is configured to: during the erase operation, receive the suspend instruction, determine a magnitude relationship between a count of the performed erase pulse suspend operations and the maximum erase pulse suspend threshold, and determine whether to perform the suspend operation in response to the suspend instruction. The maximum erase pulse suspend threshold is less than or equal to the maximum erase suspend threshold.

In some examples, the memory system comprises a control logic circuit and a buffer circuit. The control logic circuit is coupled with a memory cell array of the memory devices, and configured to: receive the suspend instruction, determine a magnitude relationship between the count of the performed suspend operations corresponding to the type of the current operation and the preset value corresponding to the type of the current operation, control part of memory cells of the memory cell array to suspend in response to the suspend instruction, add one to the count of the performed suspend operations corresponding to the type of the current operation and store the count, or continue to perform the current operation. The control logic circuit is further configured to: after an end of the suspend operation, receive a resume instruction, and control the part of memory cells of the memory cell array to resume an operation performed prior to the suspend operation in response to the resume instruction.

The buffer circuit is coupled with the control logic circuit and comprises a plurality of registers, wherein the plurality of registers are configured to respectively store counts of performed suspend operations corresponding to different types of operations and preset values corresponding to the different types of operations.

In some examples, the memory system further comprises an internal processor, wherein the internal processor is configured to acquire a working state of the memory device and generate the suspend instruction and the resume instruction. In addition or alternatively, the internal processor is configured to, after the control logic circuit resumes the operation performed prior to the suspend operation in response to the resume instruction for a duration of a first time period, judge whether the control logic circuit receives the suspend instruction.

In some examples, the memory device comprises a NAND memory.

In the above memory system, when the suspend instruction is received during a controlled operation (e.g., a read/write, program, or erase operation) of the memory device, whether the memory device responds to the suspend instruction is first judged based on magnitude relationships between the suspend instruction and preset values corresponding to different types of operations. If the suspend instruction is responded to, the memory device is controlled to suspend the current operation and stores suspend counts corresponding to the different types of operations. As such, the memory system is able to judge by itself whether the memory device is to perform the suspend operation, improving the convenience of detecting an abnormality of the operation performed by the memory device, reducing the probability of the abnormality of the operation performed by the memory device due to exceeding a preset value, and thereby improving the stability of the memory system and the memory device.

According to another aspect, the present application provides a control method of a memory system. The control method of a memory system comprises: acquiring a count of suspend operations performed in response to suspend instructions; and receiving a suspend instruction, and performing a suspend operation upon determining that the count of the performed suspend operations corresponding to a type of a current operation is less than or equal to a preset value corresponding to the type of the current operation.

In some examples, after receiving the suspend instruction, the control method further comprises: when the count of the performed suspend operations corresponding to the type of the current operation is greater than the preset value corresponding to the type of the current operation, continuing to perform the current operation without responding to the suspend instruction; and upon performing the suspend operation in response to the suspend instruction when the count of the performed suspend operations corresponding to the type of the current operation is less than or equal to the preset value corresponding to the type of the current operation, adding one to the count of the performed suspend operations corresponding to the type of the current operation and storing the count in the memory controller.

In some examples, the current operation comprises a program operation; the preset value comprises a maximum program suspend threshold; and the performed suspend operations comprise performed program suspend operations. The control method comprises: during the program operation, receiving the suspend instruction, determining a magnitude relationship between a count of the performed program suspend operations and the maximum program suspend threshold, and determining whether to perform the suspend operation in response to the suspend instruction.

In some examples, the current operation comprises an erase operation; the preset value comprises a maximum erase suspend threshold; the performed suspend operations comprise performed erase suspend operations. The control method comprises: during the erase operation, receiving the suspend instruction, determining a magnitude relationship between a count of the performed erase suspend operations and the maximum erase suspend threshold, and determining whether to perform the suspend operation in response to the suspend instruction.

In some examples, the preset value comprises a maximum erase pulse suspend threshold. The control method comprises: during the erase operation, receiving the suspend instruction, determining a magnitude relationship between a count of the performed erase pulse suspend operations and the maximum erase pulse suspend threshold, and determining whether to perform the suspend operation in response to the suspend instruction. The maximum erase pulse suspend threshold is less than or equal to the maximum erase suspend threshold.

In some examples, the control method further comprises: based on a magnitude relationship between the count of the performed suspend operations corresponding to the type of the current operation and the preset value corresponding to the type of the current operation, controlling part of memory cells of the memory cell array to suspend in response to the suspend instruction, adding one to the count of the performed suspend operations corresponding to the type of the current operation and storing the count, or continuing to perform the current operation; and after an end of the suspend operation, receiving a resume instruction, and controlling the part of memory cells of the memory cell array to resume an operation performed prior to the suspend operation in response to the resume instruction.

In some examples, the control method further comprises: after resuming the operation performed prior to the suspend operation in response to the resume instruction for a duration of a first time period, judging whether the memory system receives the suspend instruction again; in the case of receiving the suspend instruction, determining the magnitude relationship between the count of the performed suspend operations and the preset value, and determining whether to perform the suspend operation in response to the suspend instruction; and in the case of not receiving the suspend instruction, continuing to perform the currently resumed operation.

In some examples, the control method further comprises: acquiring a working state of the memory device, and generating the suspend instruction and the resume instruction.

In the control method of the memory system provided by the present application, after the memory device receives the suspend instruction, whether the count of the performed suspend operations corresponding to the type of the current operation is less than or equal to the preset value corresponding to the type of the current operation is judged first. If no, the current operation is continued without responding to the suspend instruction. If yes, the current operation is suspended in response to the suspend instruction, and at the same time, one is added to the count of the performed suspend operations and then the count is stored in the memory controller. Then, after the end of the suspend operation, the resume instruction is received, and the operation performed prior to the suspend operation is resumed. After performing for the duration of the first time period, whether the memory system receives the suspend instruction again is judged, and in the case of receiving the suspend instruction, the above operation of determining the magnitude relationship between the count of the performed suspend operations corresponding to the type of the current operation and the preset value corresponding to the type of the current operation is repeated. As such, the control method of the memory system provided by the examples of the present application implements a process capable of autonomous cyclic judgment, without manual operations performed by a user, increasing the working efficiency, improving the convenience of detecting an abnormality of the operation performed by the memory device, reducing the probability of degradation of the performance (e.g., data access) of the memory device 61 due to a statistical error in the count of the suspend operations that results in many suspend operations performed by the memory device, and thereby improving the stability of the memory system and the memory device.

According to a further aspect, the present application provides an electronic apparatus. The electronic apparatus comprises the memory system excluding the internal processor as provided by any of the above examples, and a host. The host is coupled with the memory system and configured to generate and send a suspend instruction or a resume instruction to the memory system.

The beneficial effects of the electronic apparatus provided by the present application are the same as the beneficial effects of the memory system provided by any of the above examples, and are no longer repeated here.

According to a further aspect, the present application further provides an electronic apparatus. The electronic apparatus comprises the memory system as provided by any of the above examples, and a host. The host is coupled with the memory system and configured to control the memory system.

The beneficial effects of the electronic apparatus provided by the present application are the same as the beneficial effects of the memory system provided by any of the above examples, and are no longer repeated here.

### BRIEF DESCRIPTION OF THE DRAWINGS

FIG. 1 is a schematic structural diagram I of an electronic apparatus provided by an example of the present application;

FIG. 2 is a schematic structural diagram of a memory card provided by an example of the present application;

FIG. 3 is a schematic structural diagram of a Solid State Disk (SSD) provided by an example of the present application;

FIG. 4 and FIG. 5 are schematic structural diagrams of a memory device comprising a memory cell array and a peripheral circuit provided by an example of the present application;

FIG. 6 is a schematic structural diagram of a memory device comprising a page buffer group provided by an example of the present application;

FIG. 7 is a schematic structural diagram I of a memory system provided by examples of the present disclosure;

FIG. 8 is a schematic structural diagram II of a memory system provided by examples of the present disclosure;

FIG. 9 is a schematic structural diagram III of a memory system provided by examples of the present disclosure;

FIG. 10 is a schematic structural diagram II of an electronic apparatus provided by examples of the present disclosure;

FIG. 11 is a schematic structural diagram III of an electronic apparatus provided by examples of the present disclosure;

FIG. 12 is a schematic flow diagram I of a control method of a memory system provided by examples of the present disclosure;

FIG. 13 is a schematic flow diagram II of a control method of a memory system provided by examples of the present disclosure;

FIG. 14 is a schematic flow diagram III of a control method of a memory system provided by examples of the present disclosure; and

FIG. 15 is a schematic flow diagram IV of a control method of a memory system provided by examples of the present disclosure.

### DETAILED DESCRIPTION

In order to facilitate the understanding of the present application, the present application will be described below more comprehensively with reference to the relevant drawings. Preferable examples of the present application are given in the drawings. However, the present application may be implemented in many different forms, and is not limited to the examples described herein. Instead, the purpose of providing these examples is to make the disclosure of the present application more thorough and comprehensive.

Unless otherwise defined, all technical and scientific terms used herein have the same meanings as those generally understood by those skilled in the art of the present application. The terms used in the specification of the present application are only for the purpose of describing specific examples, and are not intended to limit the present application. The term “and/or” used herein comprise any and all combinations of one or more listed associated items.

The phrases “first”, “second”, and the like used in the present application do not indicate any order, quantity, or importance, but are used only for distinguishing between different constituent parts. Similarly, the phrases “one”, “a”, “the”, and the like do not indicate a quantitative limitation, but rather the existence of at least one. The phrases “include”, “comprise”, and the like mean that elements or items appearing in front of the phrases cover elements or items listed after the phrases and equivalents thereof, but do not exclude other elements or items. The phrases “connecting”, “connected”, “coupling” and the like are not limited to physical or mechanical coupling, but may comprise electrical coupling, whether direct or indirect.

It is to be understood that, reference throughout this specification to “some implementations” or “some examples” means that features, structures, or characteristics related to the example are included in at least one example of the present application. Therefore, “in some implementations” or “in some examples” presented everywhere throughout this specification does not necessarily refer to the same example. In addition, these features, structures or characteristics may be combined in one or more examples in any proper manner. It is to be understood that, in various examples of the present application, sequence numbers of the above processes do not indicate an execution sequence, and an execution sequence of various processes shall be determined by functionalities and intrinsic logics thereof, and shall constitute no limitation on an implementation process of the examples of the present application. The above sequence numbers of the examples of the present application are only for description, and do not represent goodness and badness of the examples.

It is to be noted that, the terms “include”, “comprise” or any variants thereof herein are intended to cover non-exclusive inclusion, such that a process, a method, an article or a device comprising a series of elements comprise not only those elements, but also other elements not listed explicitly, or elements inherent to this process, method, article or device. An element defined by a statement “comprising one . . . ” do not preclude the presence of another identical element in the process, method, article or device comprising this element, without more limitations.

In order to understand the present application thoroughly, detailed operations and detailed structures will be proposed in the following description to set forth the technical solution of the present application. The detailed descriptions of the preferable examples of the present application are as follows. However, the present application may also have other implementations in addition to these detailed descriptions.

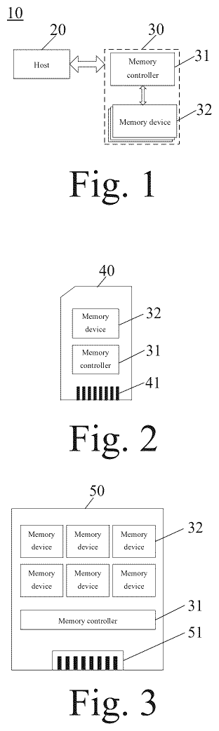

As shown in FIG. 1, examples of the present application provide an electronic apparatus 10. In an example, the electronic apparatus 10 may include, but is not limited to, a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memory devices 32 therein.

With continued reference to FIG. 1, the electronic apparatus 10 may comprise a host 20 and a memory system 30.

The host 20 may be a processor (e.g., a Central Processing Unit (CPU)) or a System on a Chip (SoC) (e.g., an Application Processor (AP)) of the electronic apparatus 10. The host 20 may be configured to send data to the memory system 30 or receive data from the memory system 30.

The memory system 30 comprises a memory controller 31 and one or more memory devices 32, as well as other integrated circuit structures for signal transmission. The memory controller 31 and one or more memory devices 32 may be integrated and packaged in the same storage apparatus. This facilitates the application of the memory system 30 to different types of end electronic products.

In an example, types of the storage apparatus in which the memory controller 31 and one or more memory devices 32 are integrated include other types of storage apparatuses such as a Universal Flash Storage (UFS) or an Embedded Multi Media Card (eMMC).

There are various schemes for integrated circuits of the storage apparatus, e.g., a memory card 40 (as shown in FIG. 2) formed by integrating a single memory device 32 and the memory controller 31 together, or an SSD 50 (as shown in FIG. 3) formed by integrating a plurality of memory devices 32 and the memory controller 31 together.

In an example, the memory card 40 may include one or more types of storage apparatuses selected from a Personal Computer Memory Card International Association (PC) card, a CF card, a Smart Media (SM) card, a memory stick, a Multi-Media Card (MMC, Reduced-Size MMC (RS-MMC), and MMCmicro), an SD (SD, miniSD, microSD, Secure Digital High Capacity (SDHC)) card, and a UFS, etc.

With continued reference to FIG. 2, the memory card 40 further comprises a memory card connector 41. The memory card connector 41 is configured to couple the memory card 40 with a host (e.g., the host 20 in FIG. 1). For example, the memory card connector 41 includes a gold finger.

Alternatively, with continued reference to FIG. 3, the SSD 50 further comprises an SSD connector 51. The SSD connector 51 is configured to couple the SSD 50 with a host (e.g., the host 20 in FIG. 1). For example, the SSD connector 51 includes a gold finger.

It may be understood that a storage capacity and/or an operation speed of the SSD 50 are greater than a storage capacity and/or an operation speed of the memory card 40.

The memory controller 31 and the memory device 32 integrated in the same storage apparatus are coupled (with the host 20), and the memory controller 31 is configured to control the memory device 32.

In an example, the memory controller 31 may be designed for operating in a low duty-cycle environment, e.g., operating in a Secure Digital (SD) card, a Compact Flash (CF) card, or a Universal Serial Bus (USB) flash drive, or operating in other media for use in electronic apparatuses such as a personal computer, a digital camera, and a mobile phone, etc. In a further example, the memory controller 31 may be designed for operating in a high duty-cycle environment, e.g., operating in an SSD or an embedded Multi-Media Card (eMMC). The SSD or eMMC may be used as a data memory for a mobile apparatus, such as a smartphone, a tablet computer, or a laptop computer, etc., or an enterprise memory array.

Further, the memory controller 31 can manage data in the memory device 32 and communicate with the host 20. The memory controller 31 may be configured to control read, erase and program operations of the memory device 32, may be further configured to manage various functions with respect to data stored or to be stored in the memory device 32, comprising, but not limited to, bad-block management, garbage collection, logical-to-physical address conversion, and wear leveling, etc., and may be further configured to process Error Checking and Correction (ECC) with respect to data read from the memory device 32 or written to the memory device 32.

Furthermore, the memory controller 31 may further perform any other suitable functions as well, e.g., formatting the memory device 32 or communicating with an external apparatus (e.g., the host 20 in FIG. 1) according to a communication protocol. For example, the memory controller 31 may communicate with the host 20 through at least one of various interface protocols. The interface protocols include one or more of a USB protocol, an MMC protocol, a Peripheral Component Interconnect (PCI) protocol, a Peripheral Component Interconnect Express (PCI-E) protocol, an Advanced Technology Attachment (ATA) protocol, a serial ATA protocol, a parallel ATA protocol, a Small Computer System Interface (SCSI) protocol, an Enhanced Small Drive Interface (ESDI) protocol, an Integrated Development Equipment (IDE) protocol, and a Firewire protocol, etc.

The memory device 32 may include, but is not limited to, one or more of a NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), and a Nano Random Access Memory (NRAM), etc.

Based on the above illustration, illustration is performed for subsequent examples of the present application through an example where the memory device 32 is a semiconductor memory, e.g., a solid state electronic device (such as a NAND memory) for storing data information that is fabricated using a semiconductor integrated circuit process. The subsequent examples of the present application do not limit a particular internal structure of the memory device 32.

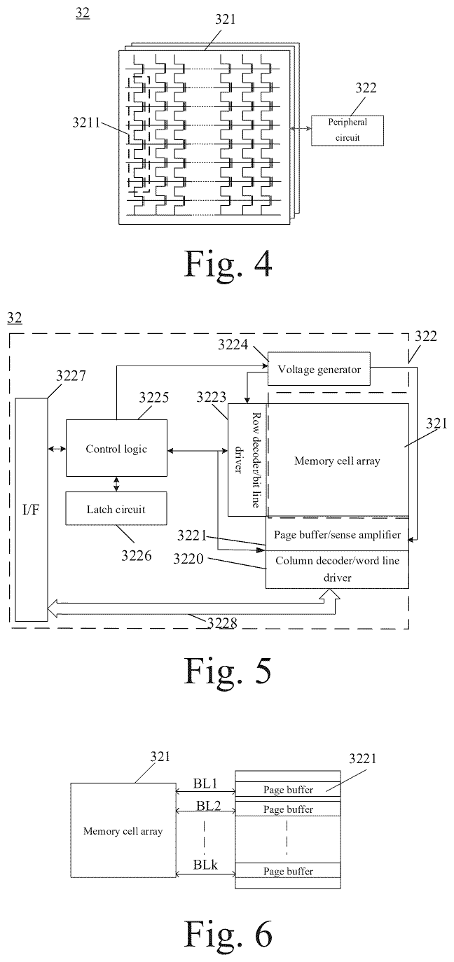

In some examples, as shown in FIG. 4, the memory device 32 may comprise a memory cell array 321 and a circuit structure such as a peripheral circuit 322 coupled to the memory cell array 321, etc.

The memory cell array 321 is coupled with a plurality of bit lines (BLs). In an example, the memory cell array 321 may be a NAND flash memory cell array. For example, the memory cell array 321 is a circuit structure disposed in the form of an array arrangement of NAND memory strings 3211. Each NAND memory string 3211 extends perpendicularly on a substrate. In an example, each NAND memory string 3211 may comprise a plurality of memory cells that are coupled in series and stacked perpendicularly. Each memory cell performs signal transmission in a state of holding a continuous analog value (such as a voltage or charge). The analog value of the memory cell depends on a number of electrons trapped in a region of the memory cell.

In an example, each memory cell in the memory cell array 321 may be either a floating gate type memory cell that comprises a floating gate transistor, or a charge trap type memory cell that comprises a charge trap transistor. The present application do not impose limitations thereto.

In some examples, the memory type of the above memory cell includes any one of a Single Level Cell (SLC), a Multi Level Cell (MLC), a Triple Level Cell (TLC), and a Quad Level Cell (QLC), etc.

In an example, each memory cell of the SLC may store one bit of data and has two possible memory states, e.g., a first memory state and a second memory state. The first memory state (e.g., “0”) corresponds to a first threshold voltage range, and the second memory state (e.g., “1”) corresponds to a second threshold voltage range. The second memory state (e.g., “1”) serves as an erased state, and the first memory state (e.g., “0”) serves as a programmed state.

In another example, each memory cell of the MLC may store two bits of data and has four possible memory states, e.g., a first memory state, a second memory state, a third memory state, and a fourth memory state. The first memory state (e.g., “00”) corresponds to a first threshold voltage range, the second memory state (e.g., “01”) corresponds to a second threshold voltage range, the third memory state (e.g., “10”) corresponds to a third threshold voltage range, and the fourth memory state (e.g., “11”) corresponds to a fourth threshold voltage range. The fourth memory state (e.g., “11”) serves as an erased state, and the first memory state (e.g., “00”), the second memory state (e.g., “01”) and the third memory state (e.g., “10”) serve as programmed states.

Similarly, each memory cell of the TLC may store three bits of data and has eight possible memory states. The eight memory states correspond to eight threshold voltage ranges respectively, and are no longer repeated in detail here. One of the eight memory states serves as an erased state (e.g., “111”), and the other seven memory states serve as programmed states. Furthermore, each memory cell of the QLC may store four bits of data and has sixteen possible memory states. The sixteen memory states correspond to sixteen threshold voltage ranges respectively, and are no longer repeated in detail here. One of the sixteen memory states serves as an erased state (e.g., “1111”), and the other fifteen memory states serve as programmed states.

With continued reference to FIG. 4, the abovementioned peripheral circuit 322 may be coupled to the memory cell array 321 through a Bit Line (BL), a Word Line (WL), a Source Line (SL), a Source Select Gate (SSG), and a Drain Select Gate (DSG). The peripheral circuit 322 is configured to implement logical operations (such as a program, read, or write operation) of the memory cell array 321 by applying a voltage signal and/or a current signal to each target memory cell and sensing at least one of a voltage signal or a current signal from each target memory cell via the bit line BL, the word line WL, the source line SL, the source select gate SSG, or the drain select gate DSG, etc.

In an example, the peripheral circuit 322 comprises various types of circuit structures formed using a Metal-Oxide-Semiconductor (MOS) transistor. For example, as shown in FIG. 5, the peripheral circuit 322 may comprise multiple types of circuit structures such as a row decoder/word line driver 3220, a page buffer (PB)/sense amplifier 3221, a column decoder/bit line driver 3223, a voltage generator 3224, a control logic 3225, a latch circuit 3226, an interface 3227, and a data bus 3228, etc.

Furthermore, as shown in FIG. 6, the peripheral circuit 322 may comprise a page buffer group consisting of a plurality of page buffers 3221. The page buffer group may be coupled with the memory cell array 321 via a plurality of bit lines (BL1 to BLk). One page buffer 3221 is coupled with the memory cell array 321 via one bit line. For example, as shown in FIG. 6, the plurality of page buffers 3221 may be coupled with the memory cell array 321 via the respective bit lines BL1 to BLk, respectively.

Based on the above structure of the memory device 32, the memory controller 31 is employed to control the memory device 32 to perform operations such as programming/erasing/reading, etc.

It may be understood that, in order to facilitate distinguishing from integration scheme (e.g., the memory card 40 and the SSD 50) of the memory controller 31 and the memory device 32 of the memory system 30 in different application scenarios mentioned above, the subsequent examples of the present application provide example illustration for functions of a memory device 61 and a memory controller 62 in a memory system 60 from the perspective of the memory system.

A count of suspend/resume operations during operations such as programming, erasing and reading of the memory device affects the reliability of data processing performed by the memory device, thereby affecting the performance of the memory device. For example, when the count of data suspend/resume operations exceeds a threshold of the memory device, erase operations occupy long time, affecting a write operation of the memory device, reducing data storage efficiency of the memory device, affecting a retention effect of data storage, and thereby degrading the performance of the memory device. Alternatively, when the count of data suspend/resume operations exceeds the threshold of the memory device, a memory block of the memory device is damaged, and a program write operation is unable to write data effectively, thereby degrading the data storage performance of the memory device.

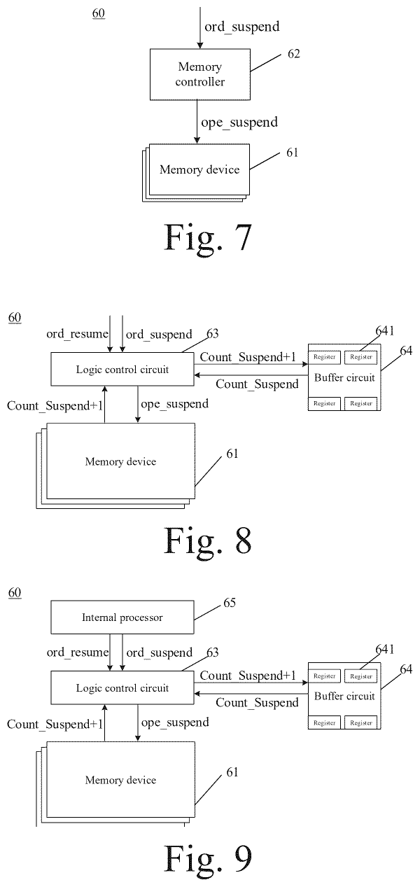

In order to solve the above problem, in some examples, as shown in FIGS. 7-9, the present application provides the memory system 60.

As shown in FIG. 7, the memory system 60 comprises one or more memory devices 61 and a memory controller 62.

In an example, the memory devices 61 comprises a NAND memory.

The memory controller 62 is coupled with the memory devices 61 and configured to: store a count Count_Suspend of suspend operations performed in response to suspend instructions ord_suspend, and after receiving a suspend instruction ord_suspend, perform the suspend operations ope_suspend upon determining that the count Count_Suspend of the performed suspend operations ope_suspend corresponding to a type of a current operation is less than or equal to a preset value Count corresponding to the type of the current operation.

It is to be noted that the above “suspend instruction” is labeled by “ord_suspend”, which does not limit a type of the suspend instruction or a type of the suspend operation implemented. Furthermore, the “suspend operation” is labeled by “ope_suspend”, so as to facilitate subsequent differentiated descriptions of different types of suspended operations based on related parameters of different types of operations, and to more clearly reflect examples of the memory device 61 based on the suspend instruction ord_suspend under different judgment conditions, e.g., “program suspend operation ope_suspend_P”, “erase suspend operation ope_suspend E”, and “read suspend operation ope_suspend_R” mentioned in the subsequent examples.

In an example, the type of the current operation comprises any one of a program operation P, an erase operation E, or a read operation R. The erase operation E comprises an actual erase stage E1 and an erase pulse stage E2.

The suspend operation comprises one or more of a program suspend operation ope_suspend_P, an erase suspend operation ope_suspend_E, and a read suspend operation ope_suspend_R.

Furthermore, the preset value Count comprises one or more of a maximum program suspend threshold MaxCount_Suspend_P, a maximum erase suspend threshold MaxCount_Suspend_E, a maximum erase pulse suspend threshold MaxCount_Suspend_E2, and a maximum read suspend count MaxCount_Suspend_R.

The erase suspend operation ope_suspend_E may be performed in the actual erase stage E1 or in the erase pulse stage E2. That is, the maximum erase suspend threshold MaxCount_Suspend_E is a larger count comprising the maximum erase pulse suspend threshold MaxCount_Suspend_E2. The present application differentiates impacts of the erase operation E on the performance of the memory device 61 by differentiating the actual erase stage E1 from the erase pulse stage E2. It may be understood that if the suspend instruction ord_suspend is received in the erase pulse stage E2, the service life of the memory block is not reduced because no actual data erasure is performed on the memory block of the memory device 61. However, if many suspend instructions ord_suspend are received in the erase pulse stage E2, the efficiency of performing the erase operation E in the actual erase stage E1 is reduced, thereby affecting the erase performance of the memory device 61. Therefore, in the actual erase stage E1 and the erase pulse stage E2, a magnitude relationship between the count Count_Suspend_E of erase suspend operations and the maximum erase suspend threshold MaxCount_Suspend_E or a magnitude relationship between the count Count_Suspend_E of erase suspend operations and the maximum erase pulse suspend threshold MaxCount_Suspend_E2 is determined respectively, to reflect different impacts on the performance of the memory device 61. The effects may be referred to the subsequent examples.

In the above memory system 60, when the suspend instruction ord_suspend is received during a controlled operation (e.g., a read, program, or erase operation) of the memory device 61, whether the memory device 61 responds to the suspend instruction ord_suspend is first determined based on magnitude relationships between the suspend instruction ord_suspend and preset values corresponding to different types of operations. In response to the suspend instruction ord_suspend, the memory device 61 is controlled to suspend the current operation and stores suspend counts corresponding to the different types of operations. As such, the memory system 60 is able to judge by itself whether the memory device 61 performs a suspend operation ope_suspend, improving the convenience of detecting the count of performed suspend operations, and reducing the probability of an operation abnormality of the memory device 61 due to the excessive count Count_Suspend of the suspend operations.

In some examples, after receiving the suspend instruction ord_suspend, the memory controller 62 is further configured to: when the count Count_Suspend of the performed suspend operations corresponding to the type (e.g., P/E/R) of the current operation is greater than the preset value Count corresponding to the type of the current operation, continue to perform the current operation without responding to the suspend instruction ord_suspend.

As such, the probability of the operation abnormality of the memory device 61 due to the excessive count Count_Suspend of the suspend operations which exceeds the preset value Count corresponding to the type of the operation of the memory device 61 is reduced, e.g., a probability of a problem such as insufficient data program write, data erase failure, or data read failure, thereby improving the stability of the memory system 60 and the memory device 61.

Moreover, upon performing the suspend operation ope_suspend in response to the suspend instruction ord_suspend when the count of the performed suspend operations ope_suspend corresponding to the type (e.g., P/E/R) of the current operation is less than or equal to the preset value Count corresponding to the type of the current operation, one is added to the count Count_Suspend of the performed suspend operations corresponding to the type of the current operation and the count is stored in the memory controller 62.

As such, by adding one to the count Count_Suspend of the performed suspend operations corresponding to the type of the current operation and storing the count in the memory controller 62, the memory system 60 may acquire the count Count_Suspend of the suspend operations by itself, facilitating the subsequent judging, based on the count Count_Suspend of the performed suspend operations, as to whether to respond to the suspend instruction ord_suspend, which eliminates the need to count by a user, such that the convenience of performing the control method of the memory system 60 in response to the suspend instruction ord_suspend is improved.

In some examples, the current operation comprises a program operation P. The preset value Count comprises the maximum program suspend threshold MaxCount_Suspend_P. The performed suspend operations ope_suspend comprise performed program suspend operations ope_suspend_P.

The memory controller 62 is configured to: during the program operation P, receive the suspend instruction ord_suspend, determine a magnitude relationship between a count Count_Suspend_P of the performed program suspend operations and the maximum program suspend threshold MaxCount_Suspend_P, and determine whether to perform the suspend operation ope_suspend in response to the suspend instruction ord_suspend.

Since the count Count_Suspend_P of the program suspend operations may affect the data write performance of the memory cell, the magnitude relationship between the count Count_Suspend_P of the performed program suspend operations and the maximum program suspend threshold MaxCount_Suspend_P is determined, such that the suspend operation is performed when the count Count_Suspend_P of the performed program suspend operations is less than or equal to the maximum program suspend threshold MaxCount_Suspend_P, so as to achieve good data write performance, thereby reducing a probability of failing to completely write data to the memory cell due to frequent suspensions during data writing.

In some other examples, the current operation comprises a read operation R. The preset value Count comprises the maximum read suspend count MaxCount_Suspend_R. The performed suspend operations ope_suspend comprise performed read suspend operations ope_suspend_R.

The memory controller 62 is configured to: during the read operation R, receive the suspend instruction ord_suspend, determine a magnitude relationship between a count Count_Suspend_R of the performed read suspend operations and the maximum read suspend count MaxCount_Suspend_R, and determine whether to perform the suspend operation ope_suspend in response to the suspend instruction ord_suspend.

Since the count Count_Suspend_R of the read suspend operations may affect a data read response speed, the magnitude relationship between the count Count_Suspend_R of the performed read suspend operations and the maximum read suspend count MaxCount_Suspend_R is determined, such that when the count Count_Suspend_R of the performed read suspend operations is less than the maximum read suspend count MaxCount_Suspend_R, it is facilitated to achieve fast data read response.

In still other examples, the current operation comprises an erase operation E. The erase operation E comprises the actual erase stage E1 and the erase pulse stage E2.

It may be understood that during the erase operation E, an entire process of the erase operation E comprises the actual erase stage E1 and the erase pulse stage E2. In the examples provided by the present application, judging whether to respond to the suspend instruction ord_suspend may be performed based on the count Count_Suspend_E of erase suspend operations performed during the entire process of the erase operation E, or based on the count Count_Suspend_E2 of erase suspend operations performed during the erase pulse stage E2. The maximum erase suspend threshold MaxCount_Suspend_E is a sum of the maximum erase pulse suspend threshold MaxCount_Suspend_E2 and the count of the suspend operations in the actual erase stage E1, that is, the maximum erase pulse suspend threshold MaxCount_Suspend_E2 is less than or equal to the maximum erase suspend threshold MaxCount_Suspend_E.

It may be understood that the excessive count Count_Suspend_E of the erase suspend operations performed in the actual erase stage E1 may result in failing to completely erase the data, thereby affecting subsequent data write. Moreover, the service life of the memory block may be reduced due to the excessive count of erase operations on the memory block of the memory device 61. If the suspend instruction ord_suspend is received in the erase pulse stage E2, the service life of the memory block is not reduced because no actual data erasure is performed on the memory block of the memory device 61. However, if many suspend instructions ord_suspend are received in the erase pulse stage E2, the efficiency of performing the erase operation E in the actual erase stage E1 is reduced, thereby affecting the erase performance of the memory device 61. Therefore, it is compared, in the actual erase stage E1 and the erase pulse stage E2, the magnitude relationship between the count Count_Suspend_E of the erase suspend operations and the maximum erase suspend threshold MaxCount_Suspend_E, the magnitude relationship between the count Count_Suspend_E of the erase suspend operations and the count Count_Suspend_E of the erase suspend operations and the maximum erase pulse suspend threshold MaxCount_Suspend_E2, or the magnitude relationship between the count Count_Suspend_E of the erase suspend operations and the maximum erase pulse suspend threshold MaxCount_Suspend_E2 is determined respectively, to reflect different impacts on the performance of the memory device 61 through above three situations.

The present application differentiates impacts of the erase operation E on the performance of the memory device 61 by differentiating the actual erase stage E1 from the erase pulse stage E2.

In an example, the preset value Count comprises the maximum erase suspend threshold MaxCount_Suspend_E. The performed suspend operations ope_suspend comprise performed erase suspend operations ope_suspend_E.

The memory controller 62 is configured to: during the erase operation E, receive the suspend instruction ord_suspend, determine a magnitude relationship between a count Count_Suspend_E of the performed erase suspend operations and the maximum erase suspend threshold MaxCount_Suspend_E, and determine whether to perform the suspend operation ope_suspend in response to the suspend instruction ord_suspend.

In another example, the preset value Count comprises the maximum erase pulse suspend threshold MaxCount_Suspend_E2. The performed suspend operations ope_suspend comprise performed erase pulse suspend operations ope_suspend_E2.

The memory controller 62 is configured to: during the erase operation E, receive the suspend instruction ord_suspend, determine a magnitude relationship between a count Count_Suspend_E2 of the performed erase pulse suspend operations and the maximum erase pulse suspend threshold MaxCount_Suspend_E2, and determine whether to perform the suspend operation ope_suspend in response to the suspend instruction ord_suspend.

The maximum erase pulse suspend threshold MaxCount_Suspend_E2 is less than or equal to the maximum erase suspend threshold MaxCount_Suspend_E.

It may be understood that the count Count_Suspend_E2 of the erase pulse suspend operations and the count Count_Suspend_E of the erase suspend operations each refer to the count of suspend operations performed during the erase operation. As a stage of performing the erase operation may comprise the actual erase stage E1 and the erase pulse stage E2, an actual stage of starting to perform the suspend operation may be identified based on the count Count_Suspend_E2 of the erase pulse suspend operations and the count Count_Suspend_E of the erase suspend operations.

As such, since the maximum erase pulse suspend threshold MaxCount_Suspend_E2 is less than or equal to the maximum erase suspend threshold MaxCount_Suspend_E, the count Count_Suspend_E of the performed erase suspend operations (or the count Count_Suspend_E2 of the erase pulse suspend operations) may be greater than the maximum erase pulse suspend threshold MaxCount_Suspend_E2 and less than or equal to the maximum erase suspend threshold MaxCount_Suspend_E. Accordingly, the suspend operation is performed in response to the suspend instruction ord_suspend; meanwhile, one is added to the count Count_Suspend_E of the performed erase suspend operations and the count is stored in the memory controller 62. Then, judging whether the count Count_Suspend_E2 of the erase pulse suspend operations (or the count Count_Suspend_E of the erase suspend operations) is less than or equal to the maximum erase suspend threshold MaxCount_Suspend_E is continued. An example situation may be set according to an application scenario of the memory device 61.

In some examples, as shown in FIG. 8, the memory system 60 comprises a control logic circuit 63 and a buffer circuit 64.

The control logic circuit 63 is coupled with a memory cell array of the memory device 61, and configured to: receive the suspend instruction ord_suspend, determine a magnitude relationship between the count Count_Suspend of the performed suspend operations corresponding to the type of the current operation and the preset value Count corresponding to the type of the current operation, control part of memory cells of the memory cell array to suspend in response to the suspend instruction ord_suspend, add one to the count Count_Suspend of the performed suspend operations corresponding to the type of the current operation and store the count, or continue to perform the current operation.

The control logic circuit 63 is further configured to: after an end of the suspend operation ope_suspend, receive a resume instruction ord_resume, and control the part of memory cells of the memory cell array to resume an operation performed prior to the suspend operation ope_suspend in response to the resume instruction ord_resume.

It is to be noted that the above “resume instruction” is labeled by “ord resume”, which does not limit a type of the resume instruction or a type of the suspend operation resumed in response to the resume instruction.

The buffer circuit 64 is coupled with the control logic circuit 63 and comprises a plurality of registers 641. The plurality of registers 641 are configured to respectively store counts Count_Suspend of performed suspend operations corresponding to different types of operations and preset values Count corresponding to the different types of operations.

It is to be noted that the examples provided by the present application do not limit circuit structures of the control logic circuit 63 and the buffer circuit 64 (and the registers 641), as long as the control logic circuit 63 and the buffer circuit 64 (and the registers 641) can achieve the above required functions, and the control logic circuit 63 and the buffer circuit 64 (and the registers 641) may also have other functions. The circuit structures and functions may be set according to actual situations.

It may be understood that the memory controller 62 may comprise the control logic circuit 63 and the buffer circuit 64; alternatively, the memory system 60 may comprise the control logic circuit 63 and the buffer circuit 64, with the memory controller 62 being a separate integrated circuit, and the control logic circuit 63 and the buffer circuit 64 being other integrated circuits coupled with the memory controller 62. The present application imposes no limitations thereto.

In an example, the control logic circuit 63 receives the suspend instruction ord_suspend, and acquires the count Count_Suspend of the performed suspend operations in the buffer circuit 64. The plurality of registers 641 in the buffer circuit 64 respectively store the counts Count_Suspend of performed suspend operations corresponding to different types of operations and the preset values Count corresponding to the different types of operations.

The control logic circuit 63 determines the magnitude relationship between the count Count_Suspend of the performed suspend operations corresponding to the type of the current operation and the preset value Count corresponding to the type of the current operation, controls part of memory cells of the memory cell array to suspend in response to the suspend instruction ord_suspend, adds one to the count Count_Suspend of the performed suspend operations corresponding to the type of the current operation and stores the count in a register 641, or continues to perform the current operation.

After the end of the suspend operation ope_suspend, the control logic circuit 63 receives the resume instruction ord_resume, and controls the part of memory cells of the memory cell array to resume the operation performed prior to the suspend operation ope_suspend in response to the resume instruction ord_resume.

For example, the type of the memory cell of the memory device 61 is TLC. The maximum erase suspend threshold MaxCount_Suspend_E is 60.

A duration of the erase suspend operation ope_suspend_E is 540-560 microseconds. After an end of the erase suspend operation ope_suspend_E, the memory device 61 responds to the resume instruction ord_resume for a duration of 10 microseconds, and then resume the operation (e.g., the erase operation E) prior to the erase suspend operation ope_suspend_E, and performs the erase operation E for a duration of 360-390 microseconds.

In some examples, as shown in FIG. 9, the memory system 60 further comprises an internal processor 65.

The internal processor 65 is configured to acquire a working state of the memory device 61 and generate the suspend instruction ord_suspend and the resume instruction ord_resume.

In addition or alternatively, the internal processor 65 is configured to, after the control logic circuit 63 resumes the operation performed prior to the suspend operation ope_suspend in response to the resume instruction ord_resume for a duration of a first time period T1, judge whether the control logic circuit 63 receives the suspend instruction ord_suspend.

It may be understood that the memory controller 62 may comprise the internal processor 65; alternatively, the memory system 60 may comprise the internal processor 65, with the memory controller 62 being a separate integrated circuit, and the internal processor 65 being another integrated circuit coupled with the memory controller 62. The present application imposes no limitations thereto.

In an example, the internal processor 65 generates the suspend instruction ord_suspend. After receiving the suspend instruction ord_suspend generated by the internal processor 65 and continuing a logic operation, the control logic circuit 63 controls the part of memory cells of the memory cell array to perform the suspend operation ope_suspend in response to the suspend instruction ord_suspend, or continues to perform the current operation.

Then the internal processor 65 generates the resume instruction ord_resume. After the control logic circuit 63 receives the resume instruction ord_resume generated by the internal processor 65 and resumes the operation performed prior to the suspend operation ope_suspend for the duration of the first time period T1, the internal processor 65 determines whether the control logic circuit 63 receives the suspend instruction ord_suspend.

Furthermore, it may be understood that the suspend instruction ord_suspend and the resume instruction ord_resume may also be generated by the host, where the memory system 60 receives the instruction generated by the host and controls the working state of the memory device 61 using the memory controller 62. The internal processor 65 provided by the above examples of the present application provides an example, which does not limit an element that generates the suspend instruction ord_suspend and the resume instruction ord_resume.

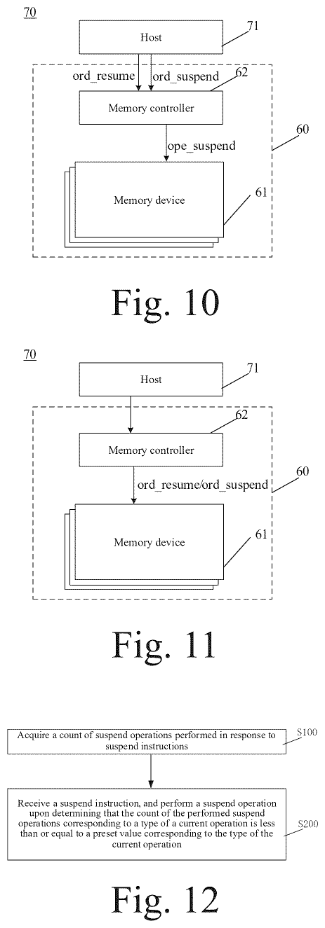

Based on the above memory system 60, as shown in FIG. 10 and FIG. 11, the present application further provides an electronic apparatus 70.

In some examples, as shown in FIG. 10, the electronic apparatus 70 comprises the memory system 60 provided by any one of the above examples, and a host 71. The host 71 is coupled with the memory system 60 and configured to generate and send the suspend instruction ord_suspend or the resume instruction ord_resume to the memory system 60. An element (e.g., the internal processor 65) in the memory system 60 does not generate the suspend instruction ord_suspend or the resume instruction ord_resume by itself.

In some other examples, as shown in FIG. 11, the electronic apparatus 70 comprises the memory system 60 provided by any one of the above examples, and the host 71. The host 71 is coupled with the memory system 60 and configured to control the memory system 60. The host 71 is configured to control the memory system 60 to perform other operations than generating the suspend instruction ord_suspend or the resume instruction ord_resume. The memory controller 62 in the memory system 60 generates the suspend instruction ord_suspend or the resume instruction ord_resume by itself, such that upon logic judgment processing, a respective operation is performed in response to the suspend instruction ord_suspend or the resume instruction ord_resume.

A difference between the above two types of electronic apparatuses 70 primarily lies in that: in one case, the host 71 sends the suspend instruction ord_suspend or the resume instruction ord_resume to the memory controller 62 of the memory system 60, and then the memory controller 62 controls the memory device 61 to perform the respective operation; in the other case, the memory controller 62 in the memory system 60 generates the suspend instruction ord_suspend or the resume instruction ord_resume and directly controls the memory device 61 to perform the respective operation. The control process may be set in a computer program, and the present application imposes no limitations thereto.

As shown in FIG. 12-FIG. 15, examples of the present application further provide a control method of the memory system 60. The control method comprises S101, S100, S200, S102, S202, and S2021.

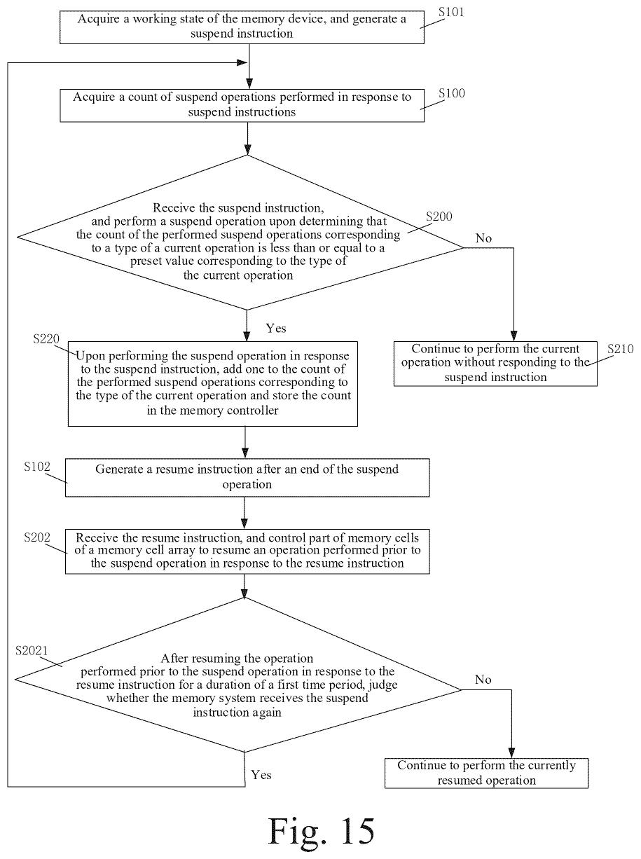

S101: As shown in FIG. 15, acquire the working state of the memory device 61, and generate the suspend instruction ord_suspend.

In an example, the internal processor 65 is configured to acquire the working state of the memory device 61 and generate the suspend instruction ord_suspend.

For example, the memory device 61 is in the process of a data program, read, or erase operation and receives the suspend instruction ord_suspend generated by the internal processor 65.

S100: As shown in FIG. 12, the count Count_Suspend of the suspend operations performed in response to the suspend instructions ord_suspend is obtained.

In an example, the type of the current operation comprises any one of a program operation P, an erase operation E, or a read operation R. The count Count_Suspend of the suspend operations during the process of the program operation P and the erase operation E affects the data storage performance and the service life of the memory device 61, and count Count_Suspend of the suspend operations during the process of the read operation R affects the data read response speed of the memory device 61.

The suspend operation comprises one or more of a program suspend operation ope_suspend_P, an erase suspend operation ope_suspend_E, and a read suspend operation ope_suspend_R.

For example, during the program operation P, the suspend instruction ord_suspend is received, and the count Count_Suspend_P of the performed program suspend operations is acquired.

Alternatively, during the erase operation E, the suspend instruction ord_suspend is received, and the count Count_Suspend_E of the performed erase suspend operations is acquired.

Still alternatively, during the read operation R, the suspend instruction ord_suspend is received, and the count Count_Suspend_R of the performed read suspend operations is acquired.

In some examples, the control method further comprises S201: after receiving the suspend instruction ord_suspend generated by the internal processor 65, first determining, by the control logic circuit 63, the magnitude relationship between the count Count_Suspend of the performed suspend operations corresponding to the type of the current operation and the preset value Count corresponding to the type of the current operation. Then, based on the magnitude relationship between the count Count_Suspend of the performed suspend operations corresponding to the type of the current operation and the preset value Count corresponding to the type of the current operation, the control logic circuit 63 is configured to control part of memory cells of the memory cell array to suspend in response to the suspend instruction ord_suspend, add one to the count Count_Suspend of the performed suspend operations corresponding to the type of the current operation and store the count, or continue to perform the current operation.

The logic judgment operation S201 of the control logic circuit 63 comprises the following example S200, S102, and S202.

S200: As shown in FIG. 12, the suspend instruction ord_suspend is received, and the suspend operation ope_suspend is performed upon determining that the count Count_Suspend of the performed suspend operations corresponding to the type of the current operation is less than or equal to the preset value Count corresponding to the type of the current operation.

In an example, the preset value Count comprises one or more of a maximum program suspend threshold MaxCount_Suspend_P, a maximum erase suspend threshold MaxCount_Suspend_E, a maximum erase pulse suspend threshold MaxCount_Suspend_E2, and a maximum read suspend count MaxCount_Suspend_R.

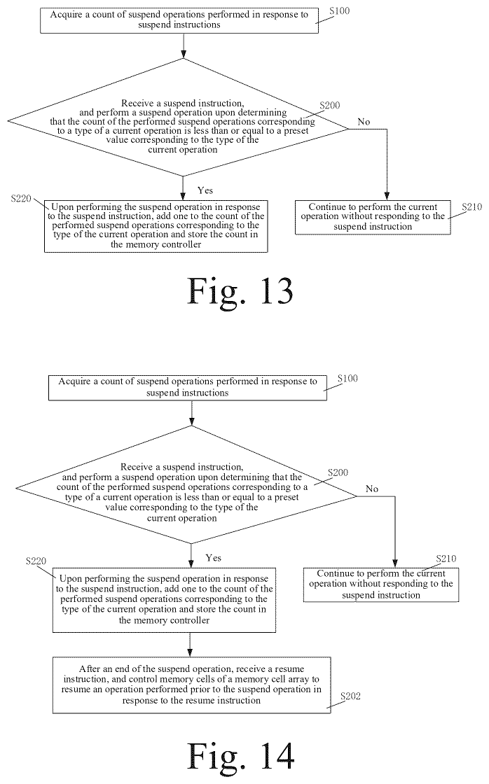

In some examples, as shown in FIG. 13, S200 comprises S210 and S220.

S210: As shown in FIG. 13, when the count of the performed suspend operations ope_suspend corresponding to the type of the current operation is greater than the preset value Count corresponding to the type of the current operation, the current operation is continued to be performed without responding to the suspend instruction ord_suspend.

For example, the current operation comprises a program operation P. When the count Count_Suspend_P of the performed program suspend operations is greater than the maximum program suspend threshold MaxCount_Suspend_P, the program operation P is continued without responding to the suspend instruction ord_suspend.

For another example, the current operation comprises an erase operation E. During a process of the erase operation E, the entire process of the erase operation E comprises the actual erase stage E1 and the erase pulse stage E2.

When the count Count_Suspend_E of the performed erase suspend operations is greater than the maximum erase suspend threshold MaxCount_Suspend_E or greater than the maximum erase pulse suspend threshold MaxCount_Suspend_E2, the erase operation E is continued without responding to the suspend instruction ord_suspend. The maximum erase suspend threshold MaxCount_Suspend_E is greater than or equal to the maximum erase pulse suspend threshold MaxCount_Suspend_E2.

For still another example, the current operation comprises a read operation R. When the count Count_Suspend_R of the performed read suspend operations is greater than the maximum read suspend count MaxCount_Suspend_R, the read operation R is continued without responding to the suspend instruction ord_suspend.

S220: As shown in FIG. 13, upon performing the suspend operation ope_suspend in response to the suspend instruction ord_suspend when the count Count_Suspend of the performed suspend operations corresponding to the type of the current operation is less than or equal to the preset value Count corresponding to the type of the current operation, one is added to the count of the performed suspend operations ope_suspend corresponding to the type of the current operation and the count is stored in the memory controller 62.

In an example, exemplary illustration is performed based on the type (e.g., the program operation P, the read operation R, and the erase operation E) of the current operation and the corresponding preset value. S220 comprises S221, S222, S223, and S224 corresponding to four implementation cases of the three operation types.

In S221, the current operation comprises the program operation P. The preset value Count comprises the maximum program suspend threshold MaxCount_Suspend_P. The performed suspend operations ope_suspend comprise performed program suspend operations ope_suspend_P.

During the program operation P, the suspend instruction ord_suspend is received, the magnitude relationship between the count Count_Suspend_P of the performed program suspend operations and the maximum program suspend threshold MaxCount_Suspend_P is determined, and whether to perform the suspend operation ope_suspend in response to the suspend instruction ord_suspend is determined.

For example, when the count Count_Suspend_P of the performed program suspend operations is less than or equal to the maximum program suspend threshold MaxCount_Suspend_P, the suspend operation ope_suspend is performed in response to the suspend instruction ord_suspend. Meanwhile, one is added to the count Count_Suspend_P of the performed program suspend operations, and the count is stored in the memory controller 62. Otherwise, the program operation P is continued without responding to the suspend instruction ord_suspend.

In S222, the current operation comprises the erase operation E. The preset value Count comprises the maximum erase suspend threshold MaxCount_Suspend_E. The performed suspend operations ope_suspend comprise performed erase suspend operations ope_suspend_E.

During the erase operation E, the suspend instruction ord_suspend is received, the magnitude relationship between the count Count_Suspend_E of the performed erase suspend operations and the maximum erase suspend threshold MaxCount_Suspend_E is determined, and whether to perform the suspend operation ope_suspend in response to the suspend instruction ord_suspend is determined.

For example, when the count Count_Suspend_E of the performed erase suspend operations is less than or equal to the maximum erase suspend threshold MaxCount_Suspend_E1, the suspend operation ope_suspend is performed in response to the suspend instruction ord_suspend. Meanwhile, one is added to the count Count_Suspend_E of the performed erase suspend operations, and the count is stored in the memory controller 62. Otherwise, the erase operation E is continued without responding to the suspend instruction ord_suspend.

In S223, the current operation comprises the erase operation E. The preset value Count comprises the maximum erase pulse suspend threshold MaxCount_Suspend_E2. The performed suspend operations ope_suspend comprise performed erase pulse suspend operations ope_suspend_E2.

During the erase operation E, the suspend instruction ord_suspend is received, the magnitude relationship between the count Count_Suspend_E2 of the performed erase pulse suspend operations and the maximum erase pulse suspend threshold MaxCount_Suspend_E2 is determined, and whether to perform the suspend operation ope_suspend in response to the suspend instruction ord_suspend is determined.

The maximum erase pulse suspend threshold MaxCount_Suspend_E2 is less than or equal to the maximum erase suspend threshold MaxCount_Suspend_E1.

For example, when the count Count_Suspend_E2 (equivalent to the count Count_Suspend_E of the erase suspend operations) of the performed erase pulse suspend operations is less than or equal to the maximum erase pulse suspend threshold MaxCount_Suspend_E2, the suspend operation ope_suspend is performed in response to the suspend instruction ord_suspend. Meanwhile, one is added to the count Count_Suspend_E of the performed erase suspend operations, and the count is stored in the memory controller 62. Otherwise, the erase operation E is continued without responding to the suspend instruction ord_suspend.

Alternatively, when the count Count_Suspend_E2 (equivalent to the count Count_Suspend_E of the erase suspend operations) of the performed erase pulse suspend operations is greater than the maximum erase pulse suspend threshold MaxCount_Suspend_E2 and less than or equal to the maximum erase suspend threshold MaxCount_Suspend_E, the suspend operation ope_suspend is performed in response to the suspend instruction ord_suspend. Meanwhile, one is added to the count Count_Suspend_E of the performed erase suspend operations, and the count is stored in the memory controller 62. Otherwise, operation S222 is performed.

It may be understood that since the maximum erase suspend threshold MaxCount_Suspend_E1 and the maximum erase suspend threshold MaxCount_Suspend_E may reflect the impacts of different performance parameters of the memory device 61, the two parameters may be used as two reference standards, to judge whether to respond to the suspend instruction ord_suspend respectively in three cases. Selection and setting are performed based on the conditions of S222 and S223 above and a current state of the memory device 61.

In S224, the current operation comprises the read operation R. When the count Count_Suspend_R of the performed read suspend operations is less than or equal to the maximum read suspend count MaxCount_Suspend_R, the suspend operation ope_suspend is performed in response to the suspend instruction ord_suspend. Meanwhile, one is added to the count Count_Suspend_R of the performed read suspend operations, and the count is stored in the memory controller 62.

For example, when the count Count_Suspend_R of the performed read suspend operations is less than or equal to the maximum read suspend count MaxCount_Suspend_R, the suspend operation ope_suspend is performed in response to the suspend instruction ord_suspend. Meanwhile, one is added to the count Count_Suspend_R of the performed read suspend operations, and the count is stored in the memory controller 62. Otherwise, the read operation R is continued without responding to the suspend instruction ord_suspend.

S102: As shown in FIG. 15, the working state of the memory device 61 is acquired, and the resume instruction ord_suspend is generated.

In an example, when the memory device 61 is in a current state of performing the suspend operation ope_suspend, the internal processor 65 generates the resume instruction ord_resume after the end of the suspend operation ope_suspend.

S202: As shown in FIG. 15, after the end of the suspend operation ope_suspend, the resume instruction ord_resume is received, and the part of memory cells of the memory cell array is controlled to resume the operation performed prior to the suspend operation ope_suspend in response to the resume instruction ord_resume.

For example, the current operation comprises the program suspend operation ope_suspend_P, and after the end of the program suspend operation ope_suspend_P, the part of memory cells of the memory cell array resume the program operation P in response to the resume instruction ord_resume.

Alternatively, the current operation comprises the erase suspend operation ope_suspend_E, and after the end of the erase suspend operation ope_suspend_E, the part of memory cells of the memory cell array resume the erase operation E in response to the resume instruction ord_resume.

Still alternatively, the current operation comprises the read suspend operation ope_suspend_R, and after the end of the read suspend operation ope_suspend_R, the part of memory cells of the memory cell array resume the read operation R in response to the resume instruction ord_resume.

Above S202 of resuming the operation performed prior to the suspend operation in response to the resume instruction ord_resume further comprises S2021.

S2021: As shown in FIG. 15, after resuming the operation performed prior to the suspend operation in response to the resume instruction ord_resume for the duration of the first time period T, it is judged whether the memory system 60 receives the suspend instruction ord_suspend again.

In the case of receiving the suspend instruction ord_suspend, the magnitude relationship between the count Count_Suspend of the performed suspend operations and the preset value Count is determined, and whether to perform the suspend operation ope_suspend in response to the suspend instruction ord_suspend is determined.

In the case of not receiving the suspend instruction ord_suspend, the currently resumed operation is continued.

In an example, the operation performed prior to the suspend operation ope_suspend is resumed based on the resume instruction ord_resume. Moreover, during the duration of the first time period T, if the internal processor 65 generates another suspend instruction ord_suspend, the memory device 61 does not receive the suspend instruction, so as to ensure that the memory device 61 may respond to the resume instruction ord_resume effectively and perform the resumed operation.

For example, time of resuming the suspend operation ope_suspend based on the resume instruction ord_resume comprises 360-390 microsecond. Considering that response time of the memory device 61 to receive the suspend instruction ord_suspend is 10 microseconds, the length of the first time period T is set to 360-390 microseconds, so as to ensure that the memory device 61 may respond to the resume instruction ord_resume effectively and perform the resumed operation, thereby reducing a probability of a system fault of the memory device 61 due to frequent reception of the suspend instructions ord_suspend for logic judgment.

In the above control method, after the memory device 61 receives the suspend instruction ord_suspend, whether the count Count_Suspend of the performed suspend operations corresponding to the type of the current operation is less than or equal to the preset value Count corresponding to the type of the current operation is judged first. If no, the current operation is continued without responding to the suspend instruction ord_suspend. If yes, the current operation is suspended in response to the suspend instruction ord_suspend, and at the same time, one is added to the count Count_Suspend of the performed suspend operations and the count is stored in the memory controller 62. Then, after the end of the suspend operation ope_suspend, the resume instruction ord_resume is received, and the operation performed prior to the suspend operation ope_suspend is resumed. After the resumption of the duration of the first time period T, whether the memory system 60 receives the suspend instruction ord_suspend again is judged, and in the case of receiving the suspend instruction ord_suspend, the above operation of determining the magnitude relationship between the count Count_Suspend of the performed suspend operations corresponding to the type of the current operation and the preset value Count corresponding to the type of the current operation is repeated in a loop. As such, the control method of the memory system 60 provided by the examples of the present application implements a process capable of autonomous cyclic judgment, without manual operations performed by a user, increasing the working efficiency, improving the convenience of detecting an abnormality of the operation performed by the memory device, reducing the probability of degradation of the data access performance of the memory device 61 due to a statistical error in the count of the suspend operations that results, and thereby improving the stability of the memory system 60 and the memory device 61.

It is to be understood that, references to “one example” or “an example” throughout this specification mean that features, structures, or characteristics related to the example are comprised in at least one example of the present disclosure. Therefore, “in one example” or “in an example” presented everywhere throughout this specification does not necessarily refer to the same example. In addition, these features, structures or characteristics may be combined in one or more examples in any proper manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples.

It is to be noted that the terms “include”, “comprise” or any variants thereof herein are intended to cover non-exclusive inclusion, such that a process, a method, an article or a device comprising a series of elements comprise not only those elements, but also other elements not listed explicitly, or elements inherent to this process, method, article or device. An element defined by a statement “comprising one . . . ” do not preclude the presence of another identical element in the process, method, article or device comprising this element, without more limitations.

The above descriptions are merely implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory system, comprising:
one or more memory devices; and
a memory controller coupled with the memory devices and configured to:
store a count of suspend operations performed in response to suspend instructions; and
after receiving a suspend instruction, perform a suspend operation upon determining that the count of the performed suspend operations corresponding to a type of a current operation is less than or equal to a preset value corresponding to the type of the current operation.

2. The memory system of claim 1, wherein after receiving the suspend instruction the memory controller is further configured to:
responsive to the count of the performed suspend operations corresponding to the type of the current operation being greater than the preset value corresponding to the type of the current operation, continue to perform the current operation without responding to the suspend instruction; and
upon performing the suspend operation in response to the suspend instruction when the count of the performed suspend operations corresponding to the type of the current operation is less than or equal to the preset value corresponding to the type of the current operation, add one to the count of the performed suspend operations corresponding to the type of the current operation and store the count in the memory controller.

3. The memory system of claim 1, wherein:
the type of the current operation comprises any one of a program operation, an erase operation, or a read operation, and
the suspend operation comprises one or more of a program suspend operation, an erase suspend operation, and a read suspend operation.

4. The memory system of claim 2, wherein the current operation comprises a program operation, the preset value comprises a maximum program suspend threshold, the performed suspend operations comprise performed program suspend operations, and
the memory controller is configured to:
during the program operation, receive the suspend instruction, determine a magnitude relationship between a count of the performed program suspend operations and the maximum program suspend threshold, and determine whether to perform the suspend operation in response to the suspend instruction.

5. The memory system of claim 2, wherein the current operation comprises an erase operation, the preset value comprises a maximum erase suspend threshold, the performed suspend operations comprise performed erase suspend operations, and
the memory controller is configured to:
during the erase operation, receive the suspend instruction, determine a magnitude relationship between a count of the performed erase suspend operations and the maximum erase suspend threshold, and determine whether to perform the suspend operation in response to the suspend instruction.

6. The memory system of claim 5, wherein the preset value comprises a maximum erase pulse suspend threshold, the performed suspend operations comprise performed erase pulse suspend operations,
the memory controller is configured to:
during the erase operation, receive the suspend instruction, determine a magnitude relationship between a count of the performed erase pulse suspend operations and the maximum erase pulse suspend threshold, and determine whether to perform the suspend operation in response to the suspend instruction, and
the maximum erase pulse suspend threshold is less than or equal to the maximum erase suspend threshold.

7. The memory system of claim 1, comprising:
a control logic circuit coupled with a memory cell array of the memory devices, and configured to: receive the suspend instruction, determine a magnitude relationship between the count of the performed suspend operations corresponding to the type of the current operation and the preset value corresponding to the type of the current operation, control part of memory cells of the memory cell array to suspend in response to the suspend instruction, add one to the count of the performed suspend operations corresponding to the type of the current operation and store the count, or continue to perform the current operation,
wherein the control logic circuit is further configured to: after an end of the suspend operation, receive a resume instruction, and control the part of memory cells of the memory cell array to resume an operation performed prior to the suspend operation in response to the resume instruction; and
a buffer circuit coupled with the control logic circuit and comprising a plurality of registers, wherein the plurality of registers are configured to respectively store counts of performed suspend operations corresponding to different types of operations and preset values corresponding to the different types of operations.

8. The memory system of claim 7, further comprising an internal processor configured to perform at least one of:
acquiring a working state of the memory device and generate the suspend instruction and the resume instruction; or
after the control logic circuit resumes the operation performed prior to the suspend operation in response to the resume instruction for a duration of a first time period, judging whether the control logic circuit receives the suspend instruction.

9. The memory system of claim 1, wherein the memory device comprises a NAND memory.

10. A control method of a memory system, comprising:
acquiring a count of suspend operations performed in response to suspend instructions; and
receiving a suspend instruction, and performing a suspend operation upon determining that the count of the performed suspend operations corresponding to a type of a current operation is less than or equal to a preset value corresponding to the type of the current operation.

11. The control method of claim 10, wherein after receiving the suspend instruction, the method further comprises:
responsive to the count of the performed suspend operations corresponding to the type of the current operation being greater than the preset value corresponding to the type of the current operation, continuing to perform the current operation without responding to the suspend instruction; and
upon performing the suspend operation in response to the suspend instruction when the count of the performed suspend operations corresponding to the type of the current operation is less than or equal to the preset value corresponding to the type of the current operation, adding one to the count of the performed suspend operations corresponding to the type of the current operation and storing the count in a memory controller.

12. The control method of claim 11, wherein the current operation comprises a program operation, the preset value comprises a maximum program suspend threshold, the performed suspend operations comprise performed program suspend operations, and
the control method comprises: during the program operation, receiving the suspend instruction, determining a magnitude relationship between a count of the performed program suspend operations and the maximum program suspend threshold, and determining whether to perform the suspend operation in response to the suspend instruction.

13. The control method of claim 11, wherein the current operation comprises an erase operation, the preset value comprises a maximum erase suspend threshold, the performed suspend operations comprise performed erase suspend operations, and
the control method comprises: during the erase operation, receiving the suspend instruction, determining a magnitude relationship between a count of the performed erase suspend operations and the maximum erase suspend threshold, and determining whether to perform the suspend operation in response to the suspend instruction.

14. The control method of claim 13, wherein the preset value comprises a maximum erase pulse suspend threshold,
the control method comprises: during the erase operation, receiving the suspend instruction, determining a magnitude relationship between a count of a performed erase pulse suspend operations and the maximum erase pulse suspend threshold, and determining whether to perform the suspend operation in response to the suspend instruction, and
the maximum erase pulse suspend threshold is less than or equal to the maximum erase suspend threshold.

15. The control method of claim 10, further comprising:
based on a magnitude relationship between the count of the performed suspend operations corresponding to the type of the current operation and the preset value corresponding to the type of the current operation, controlling part of memory cells of a memory cell array to suspend in response to the suspend instruction, adding one to the count of the performed suspend operations corresponding to the type of the current operation and storing the count, or continuing to perform the current operation; and
after an end of the suspend operation, receiving a resume instruction, and controlling the part of memory cells of the memory cell array to resume an operation performed prior to the suspend operation in response to the resume instruction.

16. The control method of claim 15, further comprising:
after resuming the operation performed prior to the suspend operation in response to the resume instruction for a duration of a first time period, judging whether the memory system receives the suspend instruction again;
responsive to receiving the suspend instruction, determining the magnitude relationship between the count of the performed suspend operations and the preset value, and determining whether to perform the suspend operation in response to the suspend instruction; and
responsive to not receiving the suspend instruction, continuing to perform the resumed operation.

17. The control method of claim 10, further comprising:
acquiring a working state of a memory device; and
generating the suspend instruction and a resume instruction.

18. The control method of claim 17, wherein the memory device comprises a NAND memory.

19. An electronic apparatus, comprising:
a memory system, comprising:
one or more memory devices; and
a memory controller coupled with the memory devices and configured to:
store a count of suspend operations performed in response to suspend instructions; and
after receiving a suspend instruction, perform a suspend operation upon determining that the count of the performed suspend operations corresponding to a type of a current operation is less than or equal to a preset value corresponding to the type of the current operation; and
a host coupled with the memory system and configured to control the memory system.

20. The electronic apparatus of claim 19, wherein the host configured to generate and send the suspend instruction or a resume instruction to the memory system.
